(19) United States
(12) Patent Application Publication
(10) Pub. No.: US 2024/0280893 A1
(43) Pub. Date: Aug. 22, 2024

(54) NANOTUBE-BASED PELLICLE FOR EXTREME ULTRAVIOLET LITHOGRAPHY AND RELATED MANUFACTURING METHOD

(71) Applicant: KOREA ELECTRONICS TECHNOLOGY INSTITUTE, Seongnam-si (KR)

(72) Inventors: Hyeong Keun KIM, Yongin-si (KR); Seul Gi KIM, Yongin-si (KR)

(21) Appl. No.: 18/411,594

(22) Filed: Jan. 12, 2024

(30) Foreign Application Priority Data
Feb. 16, 2023 (KR) 10-2023-0020459

(51) Int. Cl. G03F 1/64

(52) U.S. Cl. CPC G03F 1/64

(57) ABSTRACT

Proposed is a pellicle for extreme ultraviolet (EUV) lithography based on a nanotube and having good optical properties, thermal stability, mechanical stability and chemical durability. The pellicle may include a frame having an opening formed in a central portion, and a pellicle membrane supported by the frame and covering the opening. The pellicle membrane may be formed in a reticular structure based on nanotubes, and include a coating layer formed by coating at least part of the nanotubes with a metal or metal compound. The metal or metal compound may be based on at least one of Mo, Si, Zr, Nb, Ru, Y, La, or Ce, or any alloy thereof.

### CROSS REFERENCE TO RELATED APPLICATIONS

The present application claims priority to Korean Patent Application No. 10-2023-0020459 filed Feb. 16, 2023, the entire contents of which are incorporated herein for all purposes by this reference.

### BACKGROUND

### Technical Field

The present disclosure relates to a pellicle for extreme ultraviolet (EUV) lithography. Specifically, the disclosure relates to a pellicle for EUV lithography based on a nanotube and having good optical properties, thermal stability, mechanical stability and chemical durability, and to a related manufacturing method.

### Description of Related Technology

EUV lithography technology using a wavelength of 13.5 nm or less is used in a lithography process to improve the integration of semiconductor devices and circuits. In these days, continuous research and development is being conducted on key materials and technologies to improve the performance and efficiency of the EUV lithography process.

### SUMMARY

One aspect is a pellicle for EUV lithography based on a nanotube and having good optical properties, thermal stability, mechanical stability and chemical durability, and a related manufacturing method.

Another aspect is a pellicle for extreme ultraviolet (EUV) lithography includes a frame having an opening formed in a central portion; and a pellicle membrane supported by the frame, covering the opening, formed in a reticular structure based on nanotubes, and including a coating layer formed by coating at least part of the nanotubes with a metal or metal compound. The metal or metal compound is based on at least one of Mo, Si, Zr, Nb, Ru, Y, La, and Ce, or any alloy thereof.

The nanotubes may include at least one of a carbon nanotube (CNT), a boron nitride nanotube (BNNT), a silicon carbide nanotube (SiCNT), and a boron carbon nitride nanotube (BCNNT).

The nanotubes may include a carbon nanotube in which some carbon is replaced with at least one element or functional group from among P, S, Sr, Y, Zr, Nb, Mo, Ru, La, Ce, and Pr, or in which said element(s) or functional group(s) is attached to a surface.

The metal compound may include at least one of nitride, oxide, carbide, boride, silicide, phosphide, and sulfide.

The nanotubes may include uncoated nanotubes coated with no coating layer, and coated nanotubes coated with the coating layer.

The uncoated nanotubes and the coated nanotubes may be randomly mixed.

The pellicle membrane may include a core layer formed in a reticular structure based on the uncoated nanotubes; and a capping layer formed by laminating the coated nanotubes on at least one surface of the core layer.

The pellicle membrane may include a core layer formed in a reticular structure based on the uncoated nanotubes; and a capping layer formed by laminating the metal or the metal compound on at least one surface of the core layer. The uncoated nanotubes of the core layer located at an interface with the capping layer may be coated with the metal or the metal compound forming the capping layer, thus forming the coated nanotubes.

The pellicle membrane may include a core layer formed in a reticular structure based on the uncoated nanotubes; and a capping layer containing the coated nanotubes formed by coating the uncoated nanotubes located on at least one surface of the core layer with the metal or the metal compound.

The capping layer may be formed by coating the metal or the metal compound on the core layer and then performing heat treatment at a temperature of 200 to 1500° C.

The uncoated nanotube may be single-walled, double-walled, or multi-walled, and have a thickness of 0.3 to 100 nm. The pellicle membrane may have a thickness of 0.6 to 200 nm.

The coating layer may be formed through chemical vapor deposition (CVD), physical vapor deposition (PVD), or atomic layer deposition (ALD).

The coating layer may have a form of crystalline, amorphous, or a mixture of crystalline and amorphous.

The pellicle membrane may include an edge portion supported on the frame; and a central portion formed integrally with the edge portion and located over the opening.

The edge portion may have a higher density of the nanotubes than the central portion.

The edge portion may have a greater thickness than the central portion.

The edge portion may have a higher density of the nanotubes and a greater thickness than the central portion.

Another aspect is a method for manufacturing a pellicle membrane of a pellicle for extreme ultraviolet (EUV) lithography is provided. The pellicle membrane is formed in a reticular structure based on nanotubes, and includes a coating layer formed by coating at least part of the nanotubes with a metal or metal compound.

In the method, the uncoated nanotubes and the coated nanotubes may be randomly mixed to form the reticular structure.

The method may include forming a core layer in a reticular structure based on the uncoated nanotubes; and forming a capping layer by laminating the coated nanotubes on at least one surface of the core layer.

The method may include forming a core layer in a reticular structure based on the uncoated nanotubes; and forming a capping layer by laminating the metal or the metal compound on at least one surface of the core layer.

When the capping layer is formed, the uncoated nanotubes of the core layer located at an interface with the capping layer may be coated with the metal or the metal compound forming the capping layer, thus forming the coated nanotubes.

The method may include forming a core layer in a reticular structure based on the uncoated nanotubes; and forming a capping layer containing the coated nanotubes by coating the uncoated nanotubes located on at least one surface of the core layer with the metal or the metal compound.

The capping layer may be formed by coating the metal or the metal compound on the core layer and then performing heat treatment at a temperature of 200 to 1500° C.

In the method, the uncoated nanotubes may be carbon nanotubes, and the capping layer may contain Mo₂C formed by coating Mo and then performing heat treatment at a temperature of 200 to 1500° C.

According to the present disclosure, since the pellicle membrane is based on nanotubes including at least metal or metal compound coated nanotubes, it is possible to improve the insufficient chemical durability of the nanotubes. Also, this makes it possible to provide the pellicle for EUV lithography having improved chemical durability while maintaining the good optical properties, thermal stability, and mechanical stability provided by the nanotube-based pellicle membrane.

According to the present disclosure, in the pellicle membrane formed in a reticular structure based on nanotubes, the mechanical stability of the pellicle membrane can be improved by increasing a thickness or by increasing the density of nanotubes in the edge portion connected to the frame compared to the central portion. This allows the edge portion to absorb or disperse mechanical stress, such as shock, transmitted through the frame to the pellicle membrane, thus minimizing transmission of the stress to the central portion. Therefore, it is possible to prevent the central portion of the pellicle membrane, which is actually used for EUV lithography, from being damaged due to mechanical stress transmitted through the edge portion.

### BRIEF DESCRIPTION OF THE DRAWINGS

FIG. 1 is a plan view showing a nanotube-based pellicle for EUV lithography according to a first embodiment of the present disclosure.

FIG. 2 is an enlarged view of portion A of FIG. 1.

FIG. 3 is a diagram showing the coated nanotube of FIG. 2.

FIG. 4 is a cross-sectional view taken along line 4-4 of FIG. 1.

FIG. 5 is an enlarged view of portion B of FIG. 4.

FIG. 6 is a cross-sectional view showing a pellicle membrane of a nanotube-based pellicle for EUV lithography according to a second embodiment of the present disclosure.

FIGS. 7 and 8 are cross-sectional views showing steps in a method for manufacturing the pellicle membrane of FIG. 6.

FIG. 9 is a cross-sectional view showing a pellicle membrane of a nanotube-based pellicle for EUV lithography according to a third embodiment of the present disclosure.

FIGS. 10 and 11 are cross-sectional views showing steps in a method for manufacturing the pellicle membrane of FIG. 9.

FIG. 12 is a cross-sectional view showing a pellicle membrane of a nanotube-based pellicle for EUV lithography according to a fourth embodiment of the present disclosure.

FIGS. 13 to 15 are cross-sectional views showing steps in a method for manufacturing the pellicle membrane of FIG. 12.

FIG. 16 is a plan view showing a nanotube-based pellicle for EUV lithography according to a fifth embodiment of the present disclosure.

FIG. 17 is an enlarged view of portions C and D of FIG. 16.

FIG. 18 is a cross-sectional view showing a nanotube-based pellicle for EUV lithography according to a sixth embodiment of the present disclosure.

### DETAILED DESCRIPTION

A pellicle for EUV lithography is a component composed of a thin film (e.g., a pellicle membrane) and a frame to physically prevent contaminants generated during the EUV lithography process from adhering to a photomask. The pellicle for EUV lithography is considered an essential material to improve the yield of wafers and the productivity of the lithography process.

The conditions required for the pellicle membrane are EUV transmittance of 90% and a free-standing thin film with a thickness of several tens of nm and a size of 110×144 mm to achieve such transmittance. In addition, the pellicle membrane is an integration of cutting-edge thin film technology that requires mechanical stability not to be damaged by a horizontal acceleration of 20 g inside an EUV lithography machine and chemical stability to ensure a lifetime level of exposing 10,000 wafers in a thermal load and hydrogen radical environment caused by EUV output of 250 W (based on 5 nm node).

Because of these requirements, extreme material and process technologies are needed to manufacture the pellicle for EUV lithography. However, there are no commercially available products yet.

Metal silicide materials, which are currently used for the EUV lithography pellicle, do not have chemical resistance to chemicals exposed in the manufacturing process and are not chemically stable against hydrogen radicals generated during the EUV lithography.

Therefore, research and development on the pellicle membrane including new, chemically and thermally stable, core layer, protective layer, buffer layer, capping layer, and heat dissipation layer is being conducted around the world. In addition, the EUV light source of the current EUV lithography machine has an irradiation intensity of 250 W, but as research and development is made to achieve an output of more than 600 W, the development of materials that are more chemically and thermally stable is necessary.

Candidate materials developed so far for this purpose include thermally and chemically stable graphene, graphite, BCN, Si—BN, MoSi₂, SiC, ZrSi₂, etc., which have been proposed for a core layer, protective layer, buffer layer, or heat dissipation layer that constitute the pellicle membrane. However, it is known that in order for each candidate material to be commercialized, further improvements in crystallization technology, thickness uniformity control technology, large-area synthesis technology, and defect control technology should be made.

For example, a Si₃N₄ thin film and a Ru thin film, formed using LPCVD, have excellent chemical durability, but they are difficult to use as a protective layer due to their low EUV transmittance. Thus, there is a need to develop a protective layer having high EUV transmittance as well as high chemical resistance.

In addition, a carbon nanotube has excellent optical properties and excellent mechanical and thermal properties in the EUV lithography environment, proving its core performance as a next-generation pellicle membrane material. However, the carbon nanotube lacks chemical resistance to hydrogen radicals generated in the EUV lithography environment, so there is a need to improve the insufficient chemical durability while maintaining the optical properties, thermal stability, and mechanical stability of the carbon nanotube.

Now, embodiments of the present disclosure will be described in detail with reference to the accompanying drawings. However, in the following description and the accompanying drawings, well known techniques may not be described or illustrated in detail to avoid obscuring the subject matter of the present disclosure. Through the drawings, the same or similar reference numerals denote corresponding features consistently.

The terms and words used in the following description, drawings and claims are not limited to the bibliographical meanings thereof and are merely used by the inventor to enable a clear and consistent understanding of the disclosure. Thus, it will be apparent to those skilled in the art that the following description about various embodiments of the present disclosure is provided for illustration purpose only and not for the purpose of limiting the disclosure as defined by the appended claims and their equivalents.

### First Embodiment

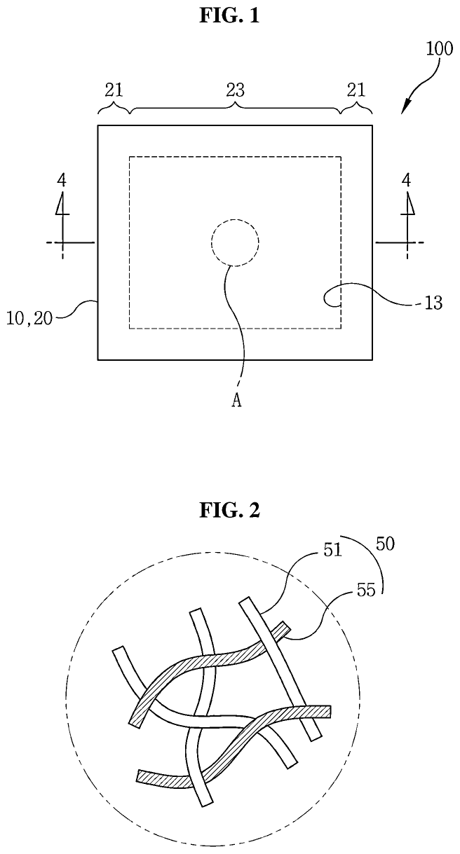

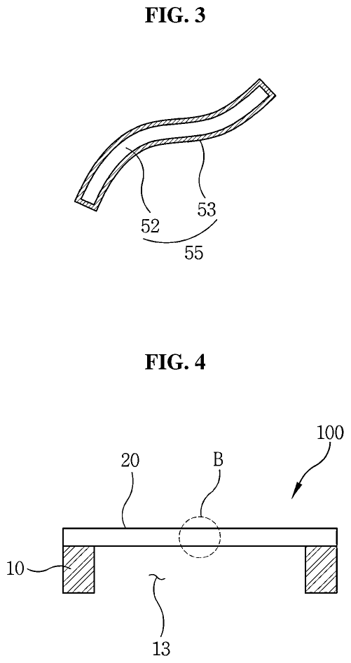

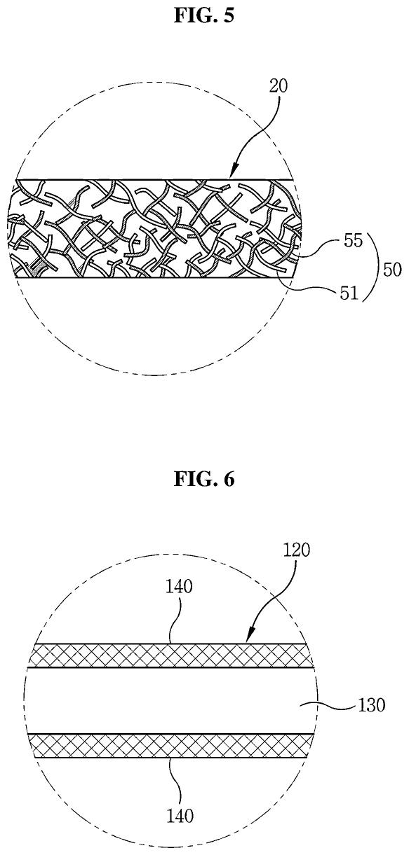

FIG. 1 is a plan view showing a nanotube-based pellicle for EUV lithography according to a first embodiment of the present disclosure. FIG. 2 is an enlarged view of portion A of FIG. 1. FIG. 3 is a diagram showing the coated nanotube of FIG. 2. FIG. 4 is a cross-sectional view taken along line 4-4 of FIG. 1. FIG. 5 is an enlarged view of portion B of FIG. 4.

Referring to FIGS. 1 to 5, a pellicle 100 for extreme ultraviolet (EUV) lithography according to the first embodiment includes a frame 10 and a pellicle membrane 20. The pellicle membrane 20 has a free-standing structure supported on the frame 10. The frame 10 has an opening 13 formed in its central portion. The pellicle membrane 20 is supported by the frame 10 and covers the opening 13. The pellicle membrane 20 is formed in a reticular structure based on nanotubes 50. The pellicle membrane 20 includes a coating layer 53 formed by coating at least part of the nanotubes 50 with a metal or metal compound. The metal or metal compound is based on at least one of Mo, Si, Zr, Nb, Ru, Y, La, and Ce, or any alloy thereof.

The nanotubes 50 forming the pellicle membrane 20 include uncoated nanotubes 51 and coated nanotubes 55. The uncoated nanotube 51 refers to a nanotube having no coating layer 53. The coated nanotube 55 refers to a nanotube in which the coating layer 53 is formed on a surface of an uncoated nanotube 52. In some cases, the pellicle membrane 20 may be entirely composed of the coated nanotube 55.

As such, the pellicle membrane 20 according to the first embodiment is based on the nanotubes 50 including at least the metal or metal compound coated nanotubes 55, so that the insufficient chemical durability of the uncoated nanotubes 51 and 52 can be improved. This makes it possible to provide the pellicle membrane 20 having good optical properties, thermal stability, mechanical stability, and chemical durability.

Hereinafter, the pellicle 100 for EUV lithography according to the first embodiment will be described in detail.

The frame 10 supports the pellicle membrane 20 and makes it easy to handle and transport the pellicle membrane 20 during the process of manufacturing the pellicle 100 for EUV lithography and after completion of manufacturing. The frame 10 may be formed of a material capable of an etching process, such as silicon. For example, the material of the frame 10 may include, but is not limited to, silicon, silicon oxide, silicon nitride, metal oxide, metal nitride, graphite, or amorphous carbon. A structure in which such materials are laminated is also possible. Here, metal may be, but is not limited to, Cr, Al, Zr, Ti, Ta, Nb, Ni, or the like.

The opening 13 may be formed in the central portion of the frame 10 using micromachining technology such as micro-electro mechanical systems (MEMS). That is, the central portion of the frame 10 is removed using micromachining technology to form the opening 13. The pellicle membrane 20 is exposed through the opening 13.

The pellicle membrane 20 is supported by the frame 10. The pellicle membrane 20 includes an edge portion 21 located on the frame 10 and a central portion 23 formed integrally with the edge portion 21 and located over the opening 13. The central portion 23 of the pellicle membrane 20 occupies more than 70% of the total area of the pellicle membrane 20.

The shape of the pellicle membrane 20 may be determined depending on the shape of the frame 10. For example, when the frame 10 has a circular or square ring shape, the pellicle membrane 20 may have a disk or square plate shape corresponding to the shape of the frame 10.

The pellicle membrane 20 is formed in a reticular structure based on the nanotubes 50. The reticular structure has a form in which the uncoated nanotubes 51 and the coated nanotubes 55 are randomly mixed. The thickness of the pellicle membrane 20 may be 0.6 to 200 nm when the nanotube 50 has a thickness of 0.3 to 100 nm.

In the pellicle membrane 20, the mixing ratio of the uncoated nanotubes 51 and the coated nanotubes 55 may be selected appropriately within a range that can improve the insufficient chemical durability of the uncoated nanotubes 51 depending on EUV lithography conditions.

The uncoated nanotubes 51 may include at least one of a carbon nanotube (CNT), a boron nitride nanotube (BNNT), a silicon carbide nanotube (SiCNT), and a boron carbon nitride nanotube (BCNNT).

The uncoated nanotubes 51 may be based on a carbon nanotube in which some carbon is replaced with at least one element or functional group from among P, S, Sr, Y, Zr, Nb, Mo, Ru, La, Ce, and Pr, or the above element(s) or functional group(s) is attached to the surface.

The uncoated nanotube 51 may be single-walled, double-walled, or multi-walled, and may have a thickness of 0.3 to 100 nm. For example, the uncoated nanotube 51 may include a carbon nanotube.

The uncoated nanotube 51 may have a tube shape with both ends open.

As shown in FIG. 3, the coated nanotube 55 includes the uncoated nanotube 52 and the coating layer 53 in which a metal or metal compound is coated on the surface of the uncoated nanotube 52. Here, the metal compound may include at least one of nitride, oxide, carbide, boride, silicide, phosphide, and sulfide. For example, the metal compound forming the coating layer 53 may be coated directly on the surface of the uncoated nanotube 52 through a deposition process. In another example, the metal compound may be formed by coating a metal of the metal compound on the surface of the uncoated nanotube 52 and then chemically reacting the coated metal and a material of the uncoated nanotube 52. For example, the metal compound may include Mo₂C based on Mo. In this case, Mo may be coated on a carbon nanotube and then reacted with the carbon nanotube through heat treatment to form Mo₂C as a coating layer on the surface of the carbon nanotube.

The coating layer 53 may be formed through a deposition process. For example, the deposition process may use chemical vapor deposition (CVD), physical vapor deposition (PVD) or atomic layer deposition (ALD). Depending on the deposition process conditions, the coating layer 53 may have the form of crystalline, amorphous, or a mixture of crystalline and amorphous.

The coating layer 53 may be formed on only the outer surface of the uncoated nanotube 52 or may be formed on both the outer surface and the inner surface. The coating layer 53 may be formed continuously to cover the entire surface of the uncoated nanotube 52 or may be formed discontinuously to cover only a part of the surface. The coating layer 51 may be formed to close at least one of open ends of the uncoated nanotube 52.

The pellicle membrane 20 according to the first embodiment can be manufactured by coating a nanotube dispersion liquid containing the coated nanotubes 55 on a sacrificial substrate and then drying it. The process of coating the nanotube dispersion liquid can be performed once or more.

Thereafter, by separating the pellicle membrane 20 from the sacrificial substrate, the pellicle membrane 20 according to the first embodiment can be obtained.

The sacrificial substrate is, for example, but not limited to, a separate substrate used for manufacturing the pellicle membrane 20. Alternatively, a frame substrate for the frame 10 may be used as the sacrificial substrate. In this case, the pellicle membrane 20 is formed on the frame substrate, and then the frame substrate is removed in part to form the opening 13. The remaining frame substrate is used as the frame 10.

Since the pellicle membrane 20 according to the first embodiment is manufactured through coating of a nanotube dispersion liquid, the uncoated nanotubes 51 and coated nanotubes 55 are randomly mixed to form a reticular structure.

In the first embodiment, the pellicle membrane 20 is formed as a single layer. This is, however, exemplary only and not considered as a limitation. Alternatively, the pellicle membrane may be formed as multiple layers. In this case, each layer may have a mixed form of uncoated nanotubes and coated nanotubes, or at least one of multiple layers may be formed of coated nanotubes only.

Since the outer surface of the pellicle membrane is the surface exposed to the EUV lithography environment, in the pellicle membrane with a multi-layered structure, the outermost layer may have the ratio of coated nanotubes higher than the ratio of uncoated nanotubes or may be formed of coated nanotubes only.

### Second Embodiment

FIG. 6 is a cross-sectional view showing a pellicle membrane 120 of a nanotube-based pellicle for EUV lithography according to a second embodiment of the present disclosure.

Referring to FIG. 6, a pellicle for EUV lithography according to the second embodiment includes a pellicle membrane 120 having a free-standing structure supported on a frame.

The pellicle membrane 120 according to the second embodiment includes a core layer 130 and capping layers 140 respectively formed on both surfaces of the core layer 130. The core layer 130 is formed in a reticular structure based on uncoated nanotubes. The capping layer 140 is formed by laminating coated nanotubes on the core layer 130.

The pellicle membrane 120 according to the second embodiment can improve the insufficient chemical durability of uncoated nanotubes by protecting the core layer 130 with the capping layer 140 formed of coated nanotubes. As a result, the pellicle membrane 120 according to the second embodiment may have good optical properties, thermal stability, mechanical stability, and chemical durability.

In the second embodiment, the core layer 130 is formed of uncoated nanotubes, and the capping layer 140 is formed of coated nanotubes. However, this is exemplary only and not considered as a limitation. Alternatively, the core layer 130 may further include coated nanotubes. In this case, the core layer 130 may have a higher ratio of uncoated nanotubes than the ratio of coated nanotubes.

Additionally, the capping layer 140 may further include uncoated nanotubes. In this case, the capping layer 140 may have a higher ratio of coated nanotubes than the ratio of uncoated nanotubes.

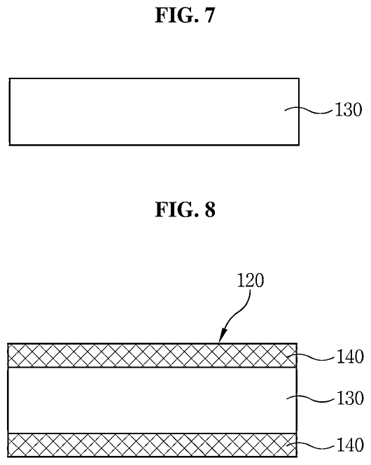

The pellicle membrane 120 according to the second embodiment can be manufactured as shown in FIGS. 7 and 8. FIGS. 7 and 8 are cross-sectional views showing steps in a method for manufacturing the pellicle membrane 120 of FIG. 6.

First, a first dispersion liquid in which uncoated nanotubes are dispersed and a second dispersion liquid in which coated nanotubes are dispersed are prepared.

Next, as shown in FIG. 7, the core layer 130 is formed by coating and drying the first dispersion liquid at least once.

In addition, as shown in FIG. 8, the capping layer 140 is formed by coating and drying the second dispersion liquid at least once on the core layer 130. As a result, the pellicle membrane 120 according to the second embodiment is manufactured.

Alternatively, in the case where the core layer 130 and the capping layer 140 have a multi-layered structure, the pellicle membrane 120 according to the second embodiment may be manufactured as follows.

The pellicle membrane 120 according to the second embodiment has a structure in which the capping layers 140 are stacked on both sides of the core layer 130. The capping layers 140 include a lower capping layer formed on the lower surface of the core layer 130 and an upper capping layer formed on the upper surface of the core layer 130.

First, the second dispersion liquid is coated and dried on the sacrificial substrate at least once to form the lower capping layer.

Next, the first dispersion liquid is coated and dried on the lower capping layer at least once to form the core layer 130.

Next, the second dispersion liquid is coated and dried on the core layer 120 at least once to form the upper capping layer. As a result, the pellicle membrane 120 according to the second embodiment is formed on the sacrificial substrate.

Then, by separating the pellicle membrane 120 from the sacrificial substrate, the pellicle membrane 120 according to the second embodiment is obtained.

In the pellicle membrane 120 according to the second embodiment, the capping layers formed of coated nanotubes are laminated on both sides of the core layer formed of uncoated nanotubes. However, this is exemplary only and not considered as a limitation. In another example, the pellicle membrane may have a structure in which uncoated nanotube layers and coated nanotube layers are alternately stacked. In this case, since the outer surface of the pellicle membrane is the surface exposed to the EUV lithography environment, the coated nanotube layer is laminated on the outer surface of the pellicle membrane.

### Third Embodiment

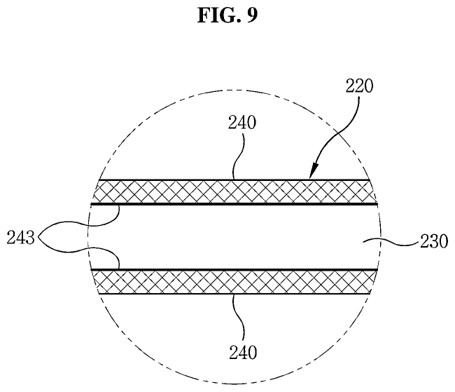

FIG. 9 is a cross-sectional view showing a pellicle membrane 220 of a nanotube-based pellicle for EUV lithography according to a third embodiment of the present disclosure.

Referring to FIG. 9, a pellicle for EUV lithography according to the third embodiment includes a pellicle membrane 220 having a free-standing structure supported on a frame.

The pellicle membrane 220 according to the third embodiment includes a core layer 230 and capping layers 240 respectively formed on both surfaces of the core layer 230. The core layer 230 is formed in a reticular structure based on uncoated nanotubes. The capping layer 240 is formed by laminating a metal or metal compound on the core layer 230.

The metal or metal compound forming the capping layer 240 is a material used for the coating layer of coated nanotubes. The uncoated nanotubes of the core layer 230 located at an interface with the capping layer 240 are coated with the metal or metal compound forming the capping layer 240, thus forming coated nanotubes. Reference numeral 243 represents the interface between the capping layer 240 and the core layer 230, and the coated nanotubes are formed on the interface 243.

As such, in the pellicle membrane 220 according to the third embodiment, among the uncoated nanotubes of the core layer 230, uncoated nanotubes located at the interface 243 between the capping layer 240 and the core layer 230 are coated with the metal or metal compound of the capping layer 240 and thus form coated nanotubes. These coated nanotubes and the capping layer 240 protect the core layer 230, thereby improving the insufficient chemical durability of the uncoated nanotube. As a result, the pellicle membrane 220 according to the third embodiment may have good optical properties, thermal stability, mechanical stability, and chemical durability.

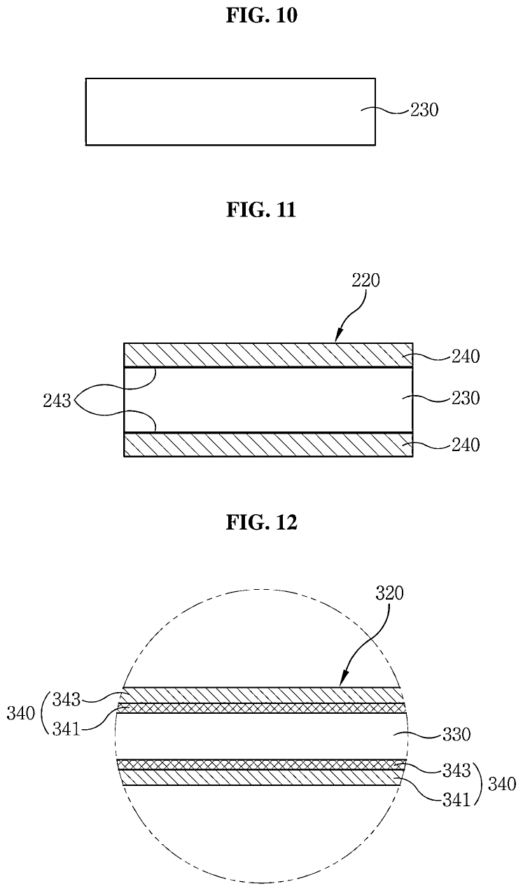

The pellicle membrane 220 according to the third embodiment can be manufactured as shown in FIGS. 10 and 11. FIGS. 10 and 11 are cross-sectional views showing steps in a method for manufacturing the pellicle membrane 220 of FIG. 9.

First, a dispersion liquid in which uncoated nanotubes are dispersed is prepared.

Next, as shown in FIG. 10, the core layer 230 is formed by coating and drying the dispersion liquid at least once.

Then, the capping layer 240 made of a metal or metal compound is formed on the core layer 230 through a deposition process. As a result, the pellicle membrane 220 according to the third embodiment is obtained.

In the process of depositing the metal or metal compound, uncoated nanotubes located at the interface 243 between the core layer 230 and the capping layer 240 are coated with the deposited metal or metal compound and thereby changed into coated nanotubes.

By adjusting the conditions of the deposition process, it is possible to appropriately adjust the thickness of the portion of the core layer 230 in which the uncoated nanotubes are changed into the coated nanotubes.

### Fourth Embodiment

FIG. 12 is a cross-sectional view showing a pellicle membrane 320 of a nanotube-based pellicle for EUV lithography according to a fourth embodiment of the present disclosure.

Referring to FIG. 12, a pellicle for EUV lithography according to the fourth embodiment includes a pellicle membrane 320 having a free-standing structure supported on a frame.

The pellicle membrane 320 according to the fourth embodiment includes a core layer 330 and capping layers 340 respectively formed on both surfaces of the core layer 330. The core layer 330 is formed in a reticular structure based on uncoated nanotubes. The capping layer 340 is formed by laminating a metal or metal compound on the core layer 330.

The metal or metal compound forming the capping layer 340 is a material used for the coating layer of coated nanotubes. To form the capping layer 340, the metal or metal compound is deposited on the core layer 330 and then heat-treated. During the deposition and heat treatment process, the uncoated nanotubes of the core layer 330 located at the interface with the capping layer 340 are coated with the metal or metal compound forming the capping layer 340, thus forming coated nanotubes.

The capping layer 340 includes a first capping layer 341 formed of the metal or metal compound on the core layer 330, and a second capping layer 343 interposed between the first capping layer 341 and the core layer 330 and containing the coated nanotubes. That is, the core layer 330 formed of the uncoated nanotubes is in contact with the second capping layer 343.

By performing the heat treatment process after the deposition process to form the capping layer 340, it is possible to increase the bonding force between the core layer 330 and the capping layer 340. When the coated nanotubes are formed, the bonding force between the uncoated nanotubes and the coating layer 340 can be increased. The depth created by the coated nanotubes in the core layer 330 can also be increased. That is, the thickness of the second capping layer 343 can be increased through control of heat treatment process conditions.

As such, in the pellicle membrane 320 according to the fourth embodiment, among the uncoated nanotubes of the core layer 330, uncoated nanotubes located at the interface between the capping layer 340 and the core layer 330 are coated with the metal or metal compound of the capping layer 340 and thus form coated nanotubes. These coated nanotubes and the capping layer 340 protect the core layer 330, thereby improving the insufficient chemical durability of the uncoated nanotube. As a result, the pellicle membrane 320 according to the fourth embodiment may have good optical properties, thermal stability, mechanical stability, and chemical durability.

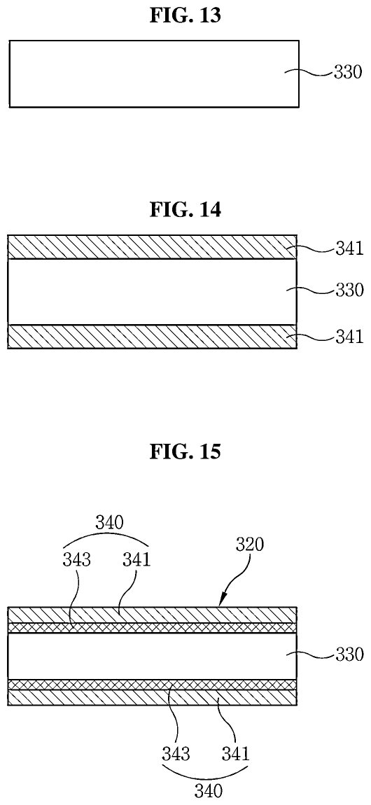

The pellicle membrane 320 according to the fourth embodiment can be manufactured as shown in FIGS. 13 to 15. FIGS. 13 to 15 are cross-sectional views showing steps in a method for manufacturing the pellicle membrane 320 of FIG. 12.

First, a dispersion liquid in which uncoated nanotubes are dispersed is prepared.

Next, as shown in FIG. 13, the core layer 330 is formed by coating and drying the dispersion liquid at least once.

Then, as shown in FIG. 14, the first capping layer 341 made of a metal or metal compound is formed on the core layer 330 through a deposition process.

In addition, as shown in FIG. 15, the first capping layer 341 is heat-treated at a temperature of 200 to 1500° C. to manufacture the pellicle membrane 320 according to the fourth embodiment. The heat treatment temperature may be appropriately selected depending on the type of metal or metal compound to be deposited.

In the process of depositing the metal or metal compound, the uncoated nanotubes located on the surface of the core layer 330 are coated with the deposited metal or metal compound and changed into coated nanotubes. That is, the second capping layer 343 is formed.

Additionally, during heat treatment after deposition, the depth of the portion in the core layer 330 where uncoated nanotubes change into coated nanotubes increases. Therefore, through deposition and heat treatment, the first capping layer 341 and the second capping layer 343 form the capping layer 340.

By controlling the conditions of the deposition and heat treatment process, the thickness of the portion of the core layer 330 that changes from the uncoated nanotube to the coated nanotube can be appropriately adjusted.

As described above, the pellicle membranes 20, 120, 220, and 320 according to the first to fourth embodiments employ coated nanotubes to improve the insufficient chemical durability of uncoated nanotubes.

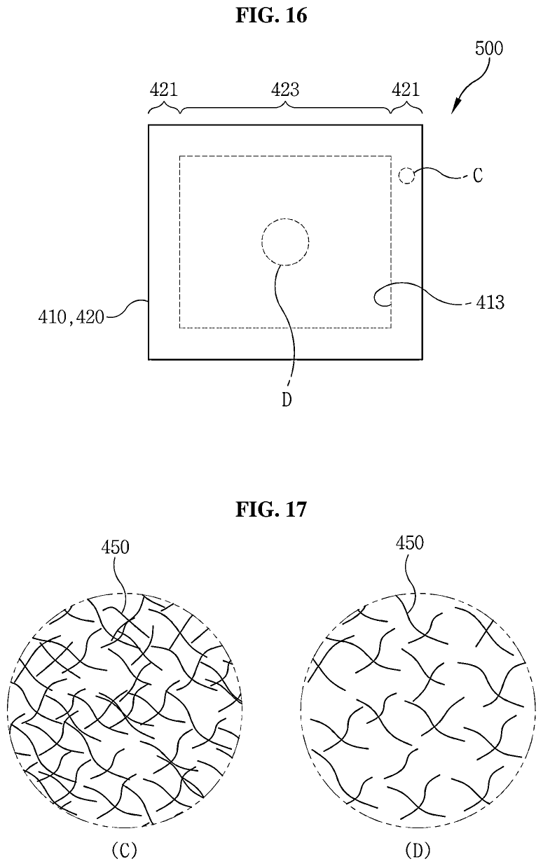

Hereinafter, in FIGS. 16 to 18, methods for improving the mechanical stability as well as the chemical durability of the pellicle membrane will be described.

### Fifth Embodiment

FIG. 16 is a plan view showing a nanotube-based pellicle 500 for EUV lithography according to a fifth embodiment of the present disclosure. (C) and (D) of FIG. 17 are enlarged views of portions C and D of FIG. 16. FIG. 17 shows the difference in density of nanotubes 450 between an edge portion and a central portion, and the nanotubes 450 distributed in the edge portion and the central portion substantially form a reticular structure.

Referring to FIGS. 16 and 17, a pellicle 500 for EUV lithography according to the fifth embodiment includes a pellicle membrane 420 having a free-standing structure supported on a frame 410.

The pellicle membrane 420 includes an edge portion 421 and a central portion 423. The edge portion 421 is supported on the frame 410, and the central portion 423 is exposed to an opening 413 formed in the frame 410.

In the pellicle membrane 420, the edge portion 421 has a higher density of nanotubes 450 than the central portion 423. To adjust the density of the nanotubes 450 between the edge portion 421 and the central portion 423, a coating process using a nanotube dispersion liquid may consider a method of coating the edge portion 421 by increasing the number of coating times compared to the central portion 423. An alternative method is to coat the edge portion 421 and the central portion 423 with nanotube dispersion liquids of different concentrations such that the nanotube dispersion liquid for the edge portion 421 has a higher concentration of nanotubes 450 than the nanotube dispersion liquid for the central portion 423.

In another method, it is possible to form the edge portion 421 and the central portion 423 together by coating the nanotube dispersion liquid at a time and then physically increase the concentration of nanotubes 450 in the edge portion 421 compared to the central portion 423 through spin.

According to the fifth embodiment, in the pellicle membrane 420 formed in a reticular structure based on the nanotubes 450, the density of the nanotubes 450 is greater in the edge portion 421 connected to the frame 410 than in the central portion 423. This is for improving the mechanical stability of the pellicle membrane 420. As a result, damage to the pellicle membrane 420 due to mechanical stress such as impact transmitted to the pellicle membrane 420 through the frame 410 can be prevented.

The density of the nanotubes 450 distributed in the edge portion 421 and the central portion 423 may increase stepwise, linearly, or non-linearly from the central portion 423 to the edge portion 421.

The pellicle membrane 420 according to the fifth embodiment may include, as the nanotubes 450, the above-described coated nanotubes in the first to fourth embodiments.

### Sixth Embodiment

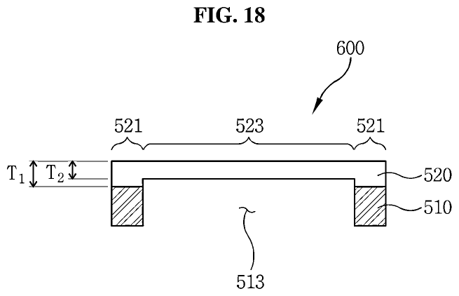

FIG. 18 is a cross-sectional view showing a nanotube-based pellicle 600 for EUV lithography according to a sixth embodiment of the present disclosure.

Referring to FIG. 18, a pellicle 600 for EUV lithography according to the sixth embodiment includes a pellicle membrane 520 having a free-standing structure supported on a frame 510.

The pellicle membrane 520 includes an edge portion 521 and a central portion 523. The edge portion 521 is supported on the frame 510, and the central portion 523 is exposed to an opening 513 formed in the frame 510.

In the pellicle membrane 520, the thickness T1 of the edge portion 521 is greater than the thickness T2 of the central portion 523. In order to adjust the thickness T1 of the edge portion 521 and the thickness T2 of the central portion 523, the coating process using a nanotube dispersion liquid may consider a method of coating the edge portion 521 with an increased number of coating times than the central portion 523. Alternatively, a method of coating the edge portion 521 and the central portion 523 to the same thickness and then half-cutting the central portion 523 may be considered. In the latter case, a nanotube disc is first formed by coating the nanotube dispersion liquid based on the thickness T1 of the edge portion 521, and then a central portion of the nanotube disc is half-cut to form the central portion 523. As a result, the pellicle membrane 520 according to the sixth embodiment can be manufactured in which the thickness T1 of the edge portion 521 is greater than the thickness T2 of the central portion 523.

According to the sixth embodiment, in the pellicle membrane 520 formed in a reticular structure based on nanotubes, the edge portion 521 connected to the frame 510 has a relatively large thickness compared to the central portion 523 (T1>T2). Therefore, the mechanical stability of the pellicle membrane 520 can be improved. As a result, damage to the pellicle membrane 520 due to mechanical stress such as impact transmitted to the pellicle membrane 520 through the frame 510 can be prevented.

Although it is shown in FIG. 18 that the edge portion 521 and the central portion 523 have a single difference in thickness T1 and T2, this is exemplary only. Alternatively, the edge portion 521 and the central portion 523 may be formed so that the thickness increases linearly or non-linearly from the central portion 523 to the edge portion 521.

The pellicle membrane 520 according to the sixth embodiment may include the above-described coated nanotubes in the first to fourth embodiments.

The fifth embodiment is a case where there is a difference in nanotube density between the edge portion 421 and the central portion 423, and the sixth embodiment is a case where there is a thickness difference between the edge portion 521 and the central portion 523. In another case, both the fifth embodiment and the sixth embodiment may be adopted together.

While the present disclosure has been particularly shown and described with reference to an exemplary embodiment thereof, it will be understood by those skilled in the art that various changes in form and details may be made therein without departing from the scope of the present disclosure as defined by the appended claims.

What is claimed is:

1. A pellicle for extreme ultraviolet (EUV) lithography, comprising:
a frame having an opening formed in a central portion; and
a pellicle membrane supported by the frame and covering the opening, formed in a reticular structure based on nanotubes, the pellicle membrane including a coating layer formed by coating at least part of the nanotubes with a metal or metal compound,
wherein the metal or metal compound is based on at least one of Mo, Si, Zr, Nb, Ru, Y, La, or Ce, or any alloy thereof.

2. The pellicle of claim 1, wherein the nanotubes include:
at least one of a carbon nanotube (CNT), a boron nitride nanotube (BNNT), a silicon carbide nanotube (SiCNT), or a boron carbon nitride nanotube (BCNNT), or
a carbon nanotube in which some carbon is replaced with at least one element or functional group from among P, S, Sr, Y, Zr, Nb, Mo, Ru, La, Ce, or Pr, or in which said element(s) or functional group(s) is attached to a surface.

3. The pellicle of claim 2, wherein the metal compound includes at least one of nitride, oxide, carbide, boride, silicide, phosphide, or sulfide.

4. The pellicle of claim 2, wherein the nanotubes include uncoated nanotubes coated with no coating layer, and coated nanotubes coated with the coating layer.

5. The pellicle of claim 4, wherein the uncoated nanotubes and the coated nanotubes are randomly mixed.

6. The pellicle of claim 4, wherein the pellicle membrane includes:
a core layer formed in a reticular structure based on the uncoated nanotubes; and
a capping layer formed by laminating the coated nanotubes on at least one surface of the core layer.

7. The pellicle of claim 4, wherein the pellicle membrane includes:
a core layer formed in a reticular structure based on the uncoated nanotubes; and
a capping layer formed by laminating the metal or the metal compound on at least one surface of the core layer,
wherein the uncoated nanotubes of the core layer located at an interface with the capping layer are coated with the metal or the metal compound forming the capping layer, to form the coated nanotubes.

8. The pellicle of claim 4, wherein the pellicle membrane includes:
a core layer formed in a reticular structure based on the uncoated nanotubes; and
a capping layer containing the coated nanotubes formed by coating the uncoated nanotubes located on at least one surface of the core layer with the metal or the metal compound.

9. The pellicle of claim 8, wherein the capping layer is formed by coating the metal or the metal compound on the core layer and then performing heat treatment at a temperature of 200° C. to 1500° C.

10. The pellicle of claim 4, wherein the uncoated nanotube are single-walled, double-walled, or multi-walled, and have a thickness of 0.3 nm to 100 nm, and
wherein the pellicle membrane has a thickness of 0.6 nm to 200 nm.

11. The pellicle of claim 1, wherein the coating layer is formed through chemical vapor deposition (CVD), physical vapor deposition (PVD), or atomic layer deposition (ALD).

12. The pellicle of claim 1, wherein the coating layer has a form of crystalline, amorphous, or a mixture of crystalline and amorphous.

13. The pellicle of claim 1, wherein the pellicle membrane includes:
an edge portion supported on the frame; and
a central portion formed integrally with the edge portion and located over the opening, and
wherein the edge portion has a higher density of the nanotubes than the central portion.

14. The pellicle of claim 1, wherein the pellicle membrane includes:
an edge portion supported on the frame; and
a central portion formed integrally with the edge portion and located over the opening,
wherein the edge portion has a greater thickness than the central portion.

15. The pellicle of claim 14, wherein the edge portion has a higher density of the nanotubes than the central portion.

16. A method for manufacturing a pellicle membrane of a pellicle for extreme ultraviolet (EUV) lithography, the method comprising:
forming the pellicle membrane in a reticular structure based on nanotubes;
coating at least part of the nanotubes with a metal or metal compound to form a coating layer of the pellicle membrane.

17. The method of claim 16, wherein the nanotubes include uncoated nanotubes coated with no coating layer, and coated nanotubes coated with the coating layer,
wherein the uncoated nanotubes and the coated nanotubes are randomly mixed to form the reticular structure.

18. The method of claim 16, wherein the nanotubes include uncoated nanotubes coated with no coating layer, and coated nanotubes coated with the coating layer,
wherein the method further comprises:
forming a core layer in a reticular structure based on the uncoated nanotubes; and
forming a capping layer by laminating the coated nanotubes on at least one surface of the core layer.

19. The method of claim 16, wherein the nanotubes include uncoated nanotubes coated with no coating layer, and coated nanotubes coated with the coating layer,
wherein the method further comprises:
forming a core layer in a reticular structure based on the uncoated nanotubes; and
forming a capping layer by laminating the metal or the metal compound on at least one surface of the core layer,
wherein when the capping layer is formed, the uncoated nanotubes of the core layer located at an interface with the capping layer are coated with the metal or the metal compound forming the capping layer, thus forming the coated nanotubes.

20. The method of claim 16, wherein the nanotubes include uncoated nanotubes coated with no coating layer, and coated nanotubes coated with the coating layer,
wherein the method further comprises:
forming a core layer in a reticular structure based on the uncoated nanotubes; and
forming a capping layer containing the coated nanotubes by coating the uncoated nanotubes located on at least one surface of the core layer with the metal or the metal compound,
wherein the capping layer is formed by coating the metal or the metal compound on the core layer and then performing heat treatment at a temperature of 200° C. to 1500° C.

21. The method of claim 20, wherein the uncoated nanotubes are carbon nanotubes, and
wherein the capping layer contains Mo₂C formed by coating Mo and then performing heat treatment at a temperature of 200° C. to 1500° C.
